(19) United States
(12) Patent Application Publication
(10) Pub. No.: US 2026/0358660 A1
(43) Pub. Date: Nov. 12, 2026

(54) DISPLAY PANEL

(71) Applicant: Coretronic Corporation, Hsin-Chu (TW)

(72) Inventors: Bo-Han Cheng, Hsin-Chu (TW); Chung-Yang Fang, Hsin-Chu (TW); Wen-Chun Wang, Hsin-Chu (TW)

(73) Assignee: Coretronic Corporation, Hsin-Chu (TW)

(21) Appl. No.: 19/663,209

(22) Filed: Apr. 29, 2026

(30) Foreign Application Priority Data
May 6, 2025 (CN) 202510574561.0

(51) Int. Cl. G02F 1/13357; G02F 1/1335; H10H 29/34

(52) U.S. Cl. CPC G02F 1/133603; G02F 1/133541; H10H 29/34

(57) ABSTRACT

A display panel includes a substrate, a first light-emitting element, a second light-emitting element, a first blue phase liquid crystal layer, and a second blue phase liquid crystal layer. The first light-emitting element is adapted to emit light having a first wavelength range. The second light-emitting element is adapted to emit light having a second wavelength range. The first blue phase liquid crystal layer overlaps the first light-emitting element. The second blue phase liquid crystal layer overlaps the second light-emitting element. An average reflectance of the first blue phase liquid crystal layer is greater than or equal to 30% in the first wavelength range, and is less than 20% in the second wavelength range. An average reflectance of the second blue phase liquid crystal layer is greater than or equal to 30% in the second wavelength range, and is less than 20% in the first wavelength range.

### CROSS-REFERENCE TO RELATED APPLICATION

This application claims the priority benefit of China application serial no. 202510574561.0, filed on May 6, 2025. The entirety of the above-mentioned patent application is hereby incorporated by reference herein and made a part of this specification.

### BACKGROUND

### Technical Field

The disclosure relates to a display panel, and more particularly to a display panel provided with a light-emitting element.

### Description of Related Art

Self-emissive displays, such as organic light-emitting diode (OLED) displays or micro light-emitting diode (micro-LED) displays, have gradually gained market popularity due to their advantages including high brightness, high contrast, wide color gamut, wide viewing angle, and fast response time. In order to improve optical efficiency and reduce power consumption, self-emissive displays are typically provided with a reflective layer to enhance the light-emitting brightness. However, the reflective layer tends to reflect ambient light, resulting in a decrease in display contrast. Accordingly, conventional self-emissive displays are additionally provided with a circular polarizer to suppress the reflection of ambient light. Nevertheless, the circular polarizer absorbs part of the light emitted by the light-emitting element, thereby reducing the display brightness.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the disclosure was acknowledged by a person of ordinary skill in the art.

### SUMMARY

To achieve one, part, or all of the aforementioned purposes or other purposes, one embodiment of the disclosure provides a display panel. The display panel includes a substrate, a first light-emitting element, a second light-emitting element, a first blue phase liquid crystal layer, and a second blue phase liquid crystal layer. The first light-emitting element is disposed on the substrate and is adapted to emit a first color light having a first wavelength range. The second light-emitting element is disposed on the substrate and is adapted to emit a second color light having a second wavelength range. The first wavelength range is different from the second wavelength range. The first blue phase liquid crystal layer is disposed on one side of a first light-emitting surface of the first light-emitting element and overlaps the first light-emitting surface. The second blue phase liquid crystal layer is disposed on one side of a second light-emitting surface of the second light-emitting element and overlaps the second light-emitting surface. An average reflectance of the first blue phase liquid crystal layer in the first wavelength range is greater than or equal to 30%, and an average reflectance thereof in the second wavelength range is less than 20%. An average reflectance of the second blue phase liquid crystal layer in the second wavelength range is greater than or equal to 30%, and an average reflectance thereof in the first wavelength range is less than 20%.

Other objectives, features and advantages of the disclosure will be further understood from the further technological features disclosed by the embodiments of the disclosure wherein there are shown and described preferred embodiments of this disclosure, simply by way of illustration of modes best suited to carry out the invention.

### BRIEF DESCRIPTION OF THE DRAWINGS

FIG. 1 is a schematic cross-sectional view of a display panel according to a first embodiment of the disclosure.

FIG. 2A is a diagram illustrating a distribution curve of reflectance versus wavelength of the first blue phase liquid crystal layer of FIG. 1.

FIG. 2B is a diagram illustrating a distribution curve of reflectance versus wavelength of the second blue phase liquid crystal layer of FIG. 1.

FIG. 2C is a diagram illustrating a distribution curve of reflectance versus wavelength of the third blue phase liquid crystal layer of FIG. 1.

FIG. 3 is a schematic cross-sectional view of a display panel according to a second embodiment of the disclosure.

### DESCRIPTION OF THE EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

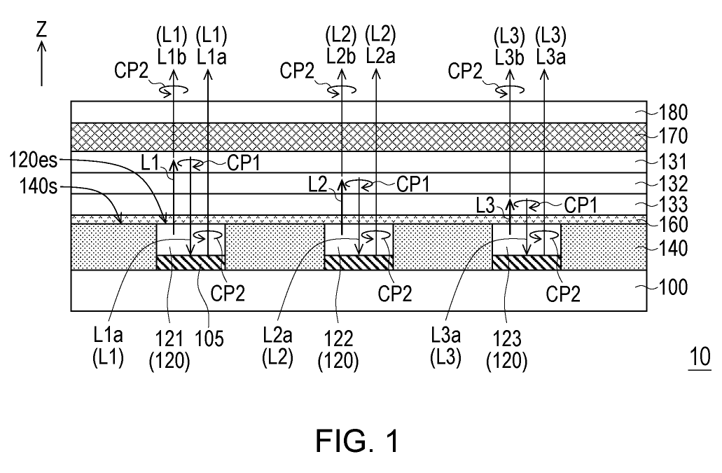

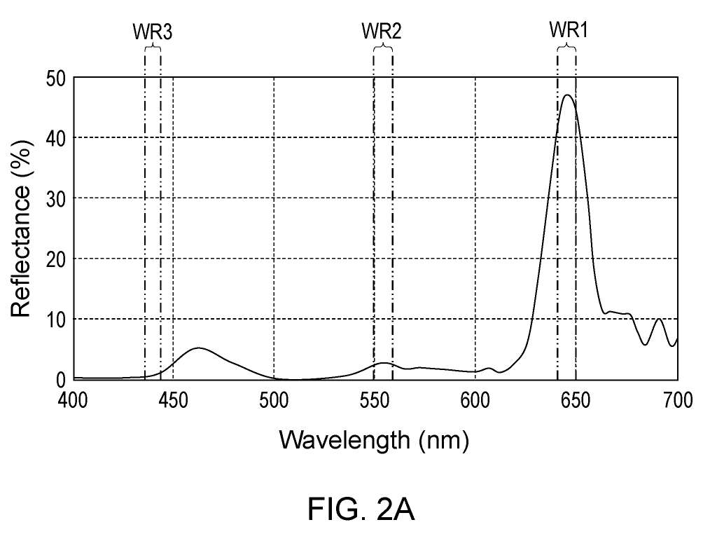

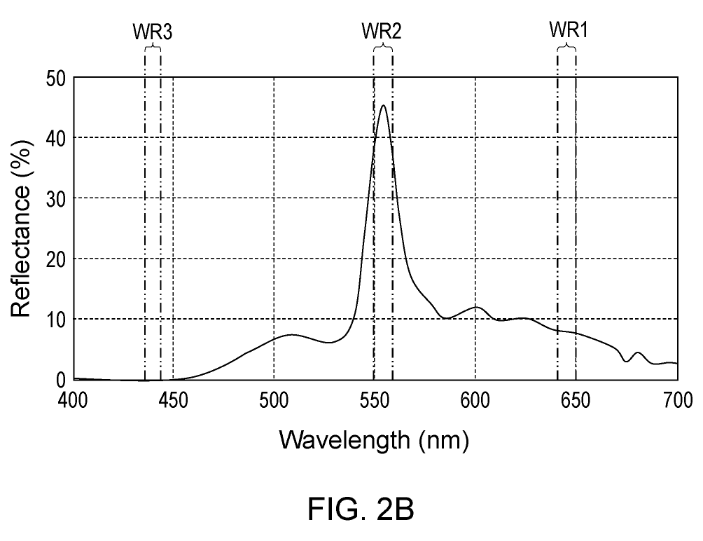

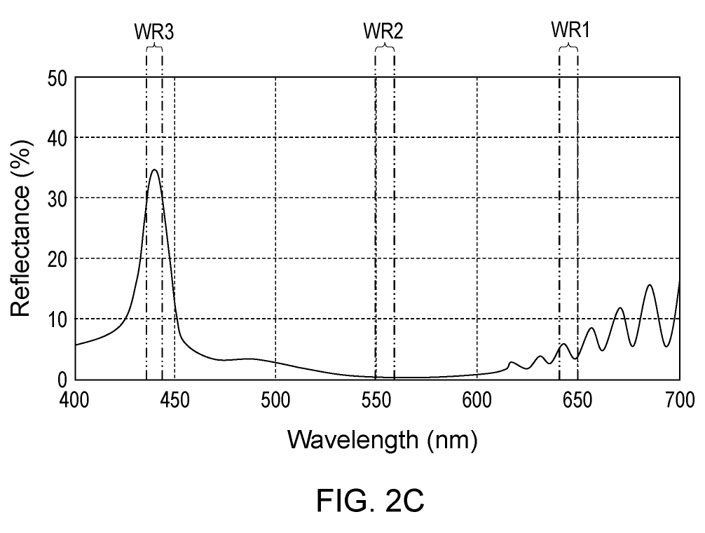

FIG. 1 is a schematic cross-sectional view of a display panel according to a first embodiment of the disclosure. FIG. 2A is a diagram illustrating a distribution curve of reflectance versus wavelength of the first blue phase liquid crystal layer of FIG. 1. FIG. 2B is a diagram illustrating a distribution curve of reflectance versus wavelength of the second blue phase liquid crystal layer of FIG. 1. FIG. 2C is a diagram illustrating a distribution curve of reflectance versus wavelength of the third blue phase liquid crystal layer of FIG. 1.

Referring to FIG. 1, a display panel 10 includes a substrate 100 and a plurality of light-emitting elements 120. The light-emitting elements 120 may include, for example, a first light-emitting element 121, a second light-emitting element 122, and a third light-emitting element 123, which may be arranged in an array on the substrate 100 and constitute a plurality of display pixels of the display panel 10. The substrate 100 may be a driving circuit board and may be provided with a plurality of pixel circuits (not shown) and a plurality of bonding pads 105. For example, each pixel circuit may include at least one thin-film transistor (e.g., an amorphous silicon, single-crystal silicon, polycrystalline silicon, or metal oxide semiconductor thin-film transistor) and at least one capacitor, and be electrically connected to at least one bonding pad 105. Each light-emitting element 120 may be bonded to at least one corresponding bonding pad 105 to be electrically coupled to the pixel circuit, and the pixel circuit is configured to control the light-emitting element 120.

In the embodiment, the material of the bonding pad 105 may include, for example, aluminum, gold, titanium, chromium, a metal alloy of the foregoing, a combination of at least two of the aforementioned metals, or other conductive materials having high reflectivity. More specifically, the bonding pad 105 in the embodiment may not only be used for bonding the light-emitting element 120, but also serve as a reflective layer to reflect light generated by the light-emitting element 120 toward the substrate 100 so that the reflected light is emitted from the light-emitting surface 120es of the light-emitting element 120, thereby improving the utilization efficiency of light energy.

The light-emitting element 120 may be, for example, a micro light-emitting diode (micro-LED), a mini light-emitting diode (mini-LED), or an organic light-emitting diode (OLED), but the disclosure is not limited thereto. For example, the light-emitting element 120 may include a p-type semiconductor layer (not shown), an n-type semiconductor layer (not shown), a light-emitting layer (not shown), and a plurality of electrodes (not shown). The light-emitting layer is disposed between the p-type semiconductor layer and the n-type semiconductor layer, and the electrodes are respectively connected to the p-type semiconductor layer and the n-type semiconductor layer, but the disclosure is not limited thereto. The material of the semiconductor layers may include, for example, AlGaInP or InGaN, and the material of the electrodes may include, for example, a metal (e.g., aluminum, gold, titanium, or chromium) or a metal oxide (e.g., indium tin oxide).

In the embodiment, each display pixel may be composed of the first light-emitting element 121, the second light-emitting element 122, and the third light-emitting element 123 that emit light having different colors, as shown in FIG. 1. One display pixel is taken as an example for explanation, but the number of display pixels in the disclosure is not limited thereto. In detail, the first light-emitting element 121, the second light-emitting element 122, and the third light-emitting element 123 are adapted to emit a first color light L1, a second color light L2, and a third color light L3 through the light-emitting surface 120es, respectively. For example, the first color light L1, the second color light L2, and the third color light L3 may be red light, green light, and blue light, respectively, but the disclosure is not limited thereto.

The display panel 10 further includes a first blue phase liquid crystal layer 131, a second blue phase liquid crystal layer 132, and a third blue phase liquid crystal layer 133, which are disposed on one side of the plurality of light-emitting elements 120 facing away from the substrate 100. For example, in the embodiment, the second blue phase liquid crystal layer 132 and the third blue phase liquid crystal layer 133 may be located between the first blue phase liquid crystal layer 131 and the substrate 100, and the second blue phase liquid crystal layer 132 may be located between the first blue phase liquid crystal layer 131 and the third blue phase liquid crystal layer 133. However, the disclosure is not limited thereto. In other embodiments, the first blue phase liquid crystal layer 131, the second blue phase liquid crystal layer 132, and the third blue phase liquid crystal layer 133 may be stacked on the substrate 100 in different sequences along a direction Z, the direction Z is, for example, perpendicular to the substrate 100 (or perpendicular to the light-emitting surface 120es). In order to bond the blue phase liquid crystal layers to the light-emitting surfaces 120es of the light-emitting elements 120, the display panel 10 may further include an adhesive layer 160. For example, the adhesive layer 160 is disposed between the third blue phase liquid crystal layer 133 and the light-emitting surfaces 120es, and the adhesive layer 160 may be formed of a material with high process compatibility, good adhesion, and low optical crosstalk.

In the embodiment, the first blue phase liquid crystal layer 131, the second blue phase liquid crystal layer 132, and the third blue phase liquid crystal layer 133 are disposed on one side of the light-emitting surface 120es of each light-emitting element 120, and these blue phase liquid crystal layers overlap the light-emitting surface 120es of the same light-emitting element 120 along the direction Z. In other words, the first blue phase liquid crystal layer 131, the second blue phase liquid crystal layer 132, and the third blue phase liquid crystal layer 133 all simultaneously overlap the light-emitting surfaces 120es of the first light-emitting element 121, the second light-emitting element 122, and the third light-emitting element 123. That is, orthographic projections of the first blue phase liquid crystal layer, the second blue phase liquid crystal layer, and the third blue phase liquid crystal layer on the substrate 100 overlap each other. However, the disclosure is not limited thereto.

In the embodiment, each of the first blue phase liquid crystal layer 131, the second blue phase liquid crystal layer 132, and the third blue phase liquid crystal layer 133 is formed, for example, by mixing reactive liquid crystal monomers, liquid crystal monomers, photoinitiators, chiral dopants, and a host medium in specific proportions. The mixing ratios of the constituent materials may be adjusted according to different material selections or process conditions, and the disclosure is not limited thereto. The reactive liquid crystal monomers and liquid crystal monomers undergo photopolymerization under ultraviolet light to stabilize the structure of the blue phase liquid crystal layers and expand their operating temperature range.

The chiral dopants enable the blue phase liquid crystal layers to exhibit chirality by forming a helical arrangement structure. When non-polarized light (e.g., natural light) within a specific wavelength range enters the blue phase liquid crystal layer, only the circularly polarized component with the same handedness as the blue phase liquid crystal layer is reflected by the blue phase liquid crystal layer, while the circularly polarized component with opposite handedness to that of the blue phase liquid crystal layer is allowed to pass through the blue phase liquid crystal layer. For example, when non-polarized light within a specific wavelength range enters a left-handed (LH) blue phase liquid crystal layer, the reflected light is left-handed circularly polarized light, and the transmitted light is right-handed circularly polarized light. Conversely, when the non-polarized light enters a right-handed (RH) blue phase liquid crystal layer, the reflected light is right-handed circularly polarized light, and the transmitted light is left-handed circularly polarized light.

From another perspective, the blue phase liquid crystal layer exhibits reflective characteristics within a specific wavelength range, and the peak wavelength and bandwidth of its reflection spectrum can be adjusted by changing the concentration ratio of its constituent materials, processing conditions (e.g., processing temperature), or by substituting materials. In the embodiment, the reflection spectra of the first blue phase liquid crystal layer 131, the second blue phase liquid crystal layer 132, and the third blue phase liquid crystal layer 133 are different from each other. For example, the first blue phase liquid crystal layer 131 exhibits a significantly higher reflectance in the red-light band (e.g., 645±20 nm) than in the green-light band (e.g., 555±20 nm) and the blue-light band (e.g., 435±20 nm), as shown in FIG. 2A, such that a portion of light within a specific wavelength range is reflected by the first blue phase liquid crystal layer 131. The second blue phase liquid crystal layer 132 exhibits significantly higher reflectance in the green-light band than in the red-light band and blue-light band, as shown in FIG. 2B. The third blue phase liquid crystal layer 133 exhibits significantly higher reflectance in the blue-light band than in the red-light band and green-light band, as shown in FIG. 2C.

Referring to FIGS. 1-2C, in the embodiment, the first color light L1 emitted by the first light-emitting element 121 has a first wavelength range WR1, which may fall within the red-light band. The second color light L2 emitted by the second light-emitting element 122 has a second wavelength range WR2, which may fall within the green-light band. The third color light L3 emitted by the third light-emitting element 123 has a third wavelength range WR3, which may fall within the blue-light band. That is, the first wavelength range WR1, the second wavelength range WR2, and the third wavelength range WR3 are different from each other. It should be noted that each of the aforementioned wavelength ranges is, for example, defined as ±5 nm around a peak emission wavelength of the light-emitting element 120, but the disclosure is not limited thereto.

More specifically, an average reflectance of the first blue phase liquid crystal layer 131 in the first wavelength range WR1 is greater than or equal to 30% (and less than 50%), and an average reflectance thereof in the second wavelength range WR2 and the third wavelength range WR3 is less than 20% (as shown in FIG. 2A). An average reflectance of the second blue phase liquid crystal layer 132 in the second wavelength range WR2 is greater than or equal to 30% (and less than 50%), and an average reflectance thereof in the first wavelength range WR1 and the third wavelength range WR3 is less than 20% (as shown in FIG. 2B). An average reflectance of the third blue phase liquid crystal layer 133 in the third wavelength range WR3 is greater than or equal to 30% (and less than 50%), and an average reflectance thereof in the first wavelength range WR1 and the second wavelength range WR2 is less than 20% (as shown in FIG. 2C). In one embodiment, the reflectance of the first blue phase liquid crystal layer 131 in the first wavelength range WR1 is greater than or equal to 30% and less than 50%, and the reflectance thereof in the second wavelength range WR2 and the third wavelength range WR2 is less than 10%. The reflectance of the second blue phase liquid crystal layer 132 in the second wavelength range WR2 is greater than or equal to 30% and less than 50%, and the reflectance thereof in the first wavelength range WR1 and the third wavelength range WR3 is less than 15%. The reflectance of the third blue phase liquid crystal layer 133 in the third wavelength range WR3 is greater than or equal to 25% and less than 50%, and the reflectance thereof in the first wavelength range WR1 and the second wavelength range WR2 is less than 15%.

Accordingly, even when a blue phase liquid crystal layer simultaneously overlaps a plurality of light-emitting elements 120 with different emission colors, only a portion of the color light whose wavelength range overlaps the reflection band of the blue phase liquid crystal layer is reflected, while the color light whose wavelength range does not overlap the reflection band can substantially pass through the blue phase liquid crystal layer.

It should be noted that the reflectance illustrated in FIGS. 2A-2C represents the reflectance of the blue phase liquid crystal layers for non-polarized light. If the incident light is circularly polarized light having a single circular polarization state (e.g., left-handed or right-handed circularly polarized light) corresponding to the handedness of blue phase liquid crystal layer, the reflectance of the blue phase liquid crystal layer for such incident light is approximately twice the reflectance shown in FIGS. 2A - 2C.

Furthermore, in order to suppress the reflection of ambient light by the display panel 10 and improve display contrast, the display panel 10 may further include a circular polarizer 170. The circular polarizer 170 is disposed overlapping the light-emitting surfaces 120es of the plurality of light-emitting elements 120 along the direction Z. The circular polarizer 170 may be a combination of a linear polarizer and a quarter-wave plate, wherein the quarter-wave plate is, for example, disposed between the linear polarizer and the light-emitting surfaces 120es, but the disclosure is not limited thereto. The first blue phase liquid crystal layer 131, the second blue phase liquid crystal layer 132, and the third blue phase liquid crystal layer 133 are located between the circular polarizer 170 and the substrate 100. It is particularly noted that the circularly polarized light (e.g., left-handed or right-handed circularly polarized light) passing through the first blue phase liquid crystal layer 131, the second blue phase liquid crystal layer 132, and the third blue phase liquid crystal layer 133 is also allowed to pass through the circular polarizer 170. In other words, the circular polarizer 170 and the three blue phase liquid crystal layers are all adapted to allow circularly polarized light of the same handedness to pass through.

Referring to FIG. 1, furthermore, the first color light L1 emitted by the first light-emitting element 121 includes a first portion L1a and a second portion L1b. The first blue phase liquid crystal layer 131 is adapted to reflect the first portion L1a of the first color light L1 and allow the second portion L1b to pass through. The second portion L1b that passes through the first blue phase liquid crystal layer 131 has a second circular polarization state CP2 and can directly pass through the circular polarizer 170.

It is particularly noted that the first portion L1a of the first color light L1 reflected by the first blue phase liquid crystal layer 131 has a first circular polarization state CP1. The first circular polarization state CP1 and the second circular polarization state CP2 may be a left-handed polarization state and a right-handed polarization state orthogonal to each other. The first portion L1a of the first color light L1 is reflected back toward the first blue phase liquid crystal layer 131 by the bonding pad 105 having reflective characteristic. After being reflected by the bonding pad 105, the polarization state of the first portion L1a changes from the first circular polarization state CP1 to the second circular polarization state CP2. Therefore, the first portion L1a, reflected by the bonding pad 105 and having the second circular polarization state CP2, can directly pass through the first blue phase liquid crystal layer 131 and the circular polarizer 170. That is, the provision of the first blue phase liquid crystal layer 131 can significantly reduce the light energy loss of the first color light L1 emitted by the first light-emitting element 121 after passing through the circular polarizer 170, thereby improving the light energy utilization.

Similarly, the second color light L2 emitted by the second light-emitting element 122 includes a first portion L2a and a second portion L2b. The second blue phase liquid crystal layer 132 is adapted to reflect the first portion L2a of the second color light L2 and allow the second portion L2b to pass through. The second portion L2b passing through the second blue phase liquid crystal layer 132 has the second circular polarization state CP2 and can directly pass through the circular polarizer 170. The first portion L2a of the second color light L2 reflected by the second blue phase liquid crystal layer 132 has the first circular polarization state CP1. The first portion L2a of the second color light L2 is reflected back toward the second blue phase liquid crystal layer 132 by the bonding pad 105 having reflective characteristic. After being reflected by the bonding pad 105, the polarization state of the first portion L2a changes from the first circular polarization state CP1 to the second circular polarization state CP2. Therefore, the first portion L2a, reflected by the bonding pad 105 and having the second circular polarization state CP2, can directly pass through the second blue phase liquid crystal layer 132 and the circular polarizer 170.

The third color light L3 emitted from the third light-emitting element 123 includes a first portion L3a and a second portion L3b. The third blue phase liquid crystal layer 133 is adapted to reflect the first portion L3a of the third color light L3 and allow the second portion L3b to pass through. The second portion L3b passing through the third blue phase liquid crystal layer 133 has a second circular polarization state CP2 and can directly pass through the circular polarizer 170. The first portion L3a of the third color light L3 reflected by the third blue phase liquid crystal layer 133 has a first circular polarization state CP1. The first portion L3a of the first color light L3 is reflected back toward the third blue phase liquid crystal layer 133 by the bonding pad 105 having reflective characteristic. After being reflected by the bonding pad 105, the polarization state of the first portion L3a changes from the first circular polarization state CP1 to the second circular polarization state CP2. Therefore, the first portion L3a, reflected by the bonding pad 105 and having the second circular polarization state CP2, can directly pass through the third blue phase liquid crystal layer 133 and the circular polarizer 170.

That is, the provision of the second blue phase liquid crystal layer 132 can significantly reduce the light energy loss of the second color light L2 emitted by the second light-emitting element 122 after passing through the circular polarizer 170, and the provision of the third blue phase liquid crystal layer 133 can significantly reduce the light energy loss of the third color light L3 emitted by the third light-emitting element 123 after passing through the circular polarizer 170, thereby improving light energy utilization.

It is particularly noted that, in current display panels, microlenses are typically disposed above the light-emitting surfaces of the light-emitting elements to increase light output near the normal viewing angle. However, to meet the high-resolution requirements of display panels, the sizes of both the light-emitting elements and the microlenses are continuously reduced, greatly increasing the alignment difficulty during fabrication. In addition, microlenses with different configurations or curvatures have to be individually designed for the light-emitting elements with different emission colors, which further increases design and process complexity. In the embodiment, the blue phase liquid crystal layers, which also serve the function of brightness enhancement, are provided as a continuous film covering the plurality of light-emitting elements 120, without incorporating any microstructures. Therefore, compared to conventional technologies, the manufacturing difficulty and design complexity of the display panel 10 can be significantly reduced.

On the other hand, since the blue phase liquid crystal layers of the embodiment have a narrower reflection bandwidth for specific color light compared to conventional cholesteric liquid crystal layers, they can more effectively suppress the reflection of ambient light, thereby providing the display panel 10 with improved display contrast. In addition, the reflection spectra of the blue phase liquid crystal layers exhibit lower dependency on the incident angle of light (e.g., blue shift of the reflection band with increasing incident angle) or on the ambient temperature compared to cholesteric liquid crystal layers. Therefore, under different viewing angles or ambient temperatures, the display panel 10 of the embodiment can maintain more consistent color performance.

To further reduce the reflection of ambient light, the display panel 10 may further include a light-absorbing layer 140. The light-absorbing layer 140 is disposed on the substrate 100 and located between the plurality of light-emitting elements 120. In the embodiment, the light-absorbing layer 140 has a surface 140s facing away from the substrate 100, and the surface 140s of the light-absorbing layer 140 may be substantially aligned with the light-emitting surface 120es of each light-emitting element 120, but the disclosure is not limited thereto. The material of the light-absorbing layer 140 may include, for example, a black resin material.

In the embodiment, the display panel 10 may further include a protective layer 180, disposed on one side of the circular polarizer 170 facing away from the substrate 100. That is, the circular polarizer 170 is disposed between the substrate 100 and the protective layer 180. The material of the protective layer 180 may include, for example, glass or other optical-grade materials having high transmittance and low reflectance. The provision of the protective layer 180 can prevent internal components (e.g., the blue phase liquid crystal layers and the light-emitting elements 120) from being damaged by external environmental influences (e.g., scratches, impacts, dust, or moisture intrusion).

It should be noted that, in other embodiments, the number of light-emitting elements 120 with different emission colors (e.g., two colors or more than three colors), as well as the number of blue phase liquid crystal layers correspondingly disposed, can be adjusted according to actual application requirements or design considerations, and the disclosure is not limited thereto.

Another embodiment is described in detail below to further illustrate the disclosure. Identical components are denoted by the same reference numerals, and descriptions of identical technical content are omitted. For the omitted portions, please refer to the aforementioned embodiments, and repeated explanations will not be provided herein.

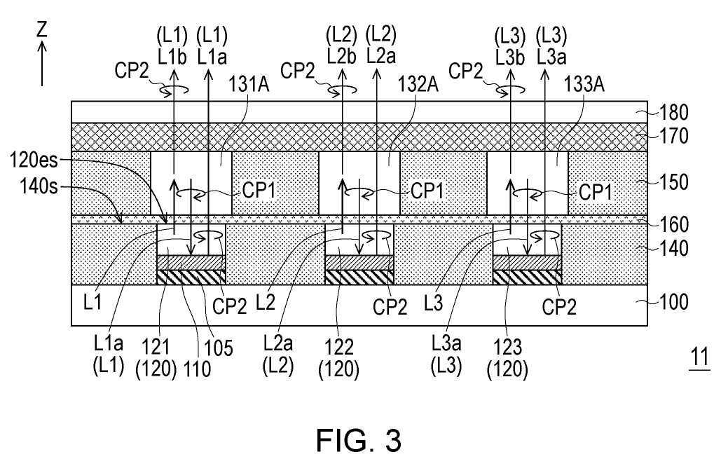

FIG. 3 is a schematic cross-sectional view of a display panel according to a second embodiment of the disclosure. Referring to FIG. 3, the main difference between a display panel 11 of the embodiment and the display panel 10 of FIG. 1 lies in the configuration relationship among the three blue phase liquid crystal layers. Specifically, in the display panel 11 of the embodiment, the orthographic projections of the first blue phase liquid crystal layer 131A, the second blue phase liquid crystal layer 132A, and the third blue phase liquid crystal layer 133A on the substrate 100 do not overlap with each other. In other words, the three blue phase liquid crystal layers of the embodiment are not stacked over the plurality of light-emitting elements 120 along the direction Z.

For example, in the direction Z, the first blue phase liquid crystal layer 131A overlaps the first light-emitting element 121 but does not overlap the second light-emitting element 122 or the third light-emitting element 123. The second blue phase liquid crystal layer 132A overlaps the second light-emitting element 122 but does not overlap the first light-emitting element 121 or the third light-emitting element 123. The third blue phase liquid crystal layer 133A overlaps the third light-emitting element 123 but does not overlap the second light-emitting element 122 or the first light-emitting element 121. That is, each blue phase liquid crystal layer overlaps only its corresponding light-emitting element. Preferably, a ratio of the orthographic projection area of the light-emitting surface 120es of each light-emitting element 120 on the substrate 100 to the orthographic projection area of the blue phase liquid crystal layer overlapping the light-emitting surface 120es on the substrate 100 is 0.75 (i.e., the orthographic projection area of the light-emitting surface 120es of each light-emitting element 120 is less than the orthographic projection area of the blue phase liquid crystal layer overlapping the light-emitting surface 120es).

For example, the first blue phase liquid crystal layer 131A, the second blue phase liquid crystal layer 132A, and the third blue phase liquid crystal layer 133A may be bonded to the light-emitting surfaces 120es of the first light-emitting element 121, the second light-emitting element 122, and the third light-emitting element 123, respectively, via the adhesive layer 160. That is, the adhesive layer 160 may connect the blue phase liquid crystal layer and the light-emitting surface 120es of the light-emitting element 120 overlapped with each other along the direction Z. In the embodiment, the display panel 11 may further include an light-absorbing layer 150, which is disposed between the first blue phase liquid crystal layer 131A, the second blue phase liquid crystal layer 132A, and the third blue phase liquid crystal layer 133A, and does not overlap the light-emitting surface 120es of each of the first light-emitting element 121, the second light-emitting element 122, and the third light-emitting element 123. The material of the light-absorbing layer 150 may include, for example, a black resin material. The light-absorbing layer 150 may be bonded to the surface 140s of the light-absorbing layer 140 via the adhesive layer 160.

Since the first blue phase liquid crystal layer 131A, the second blue phase liquid crystal layer 132A, and the third blue phase liquid crystal layer 133A of the embodiment provide technical effects (e.g., improving light energy utilization) similar to those provided by the first blue phase liquid crystal layer 131, the second blue phase liquid crystal layer 132, and the third blue phase liquid crystal layer 133 of the display panel 10 in FIG. 1, detailed descriptions can be found in the relevant paragraphs of the aforementioned embodiment and are not repeated herein.

It is particularly noted that, since the coverage area of the blue phase liquid crystal layers on the substrate 100 is significantly reduced in the embodiment, and the light-absorbing layer 150 is further provided between the blue phase liquid crystal layers, the reflection of ambient light can be effectively suppressed, thereby further enhancing the display contrast of the display panel 11.

Furthermore, in the embodiment, a reflective layer 110 may be disposed between the light-emitting element 120 and the substrate 100 to reflect the light emitted by the light-emitting element 120 toward the substrate 100 and direct it to exit from the light-emitting surface 120es, thereby enhancing the utilization efficiency of the light energy. For example, the reflective layer 110 includes a plurality of reflective pads, and orthographic projections of the first light-emitting element 121 and the second light-emitting element 122 on the substrate 100 are respectively located within orthographic projections of corresponding reflective pads on the substrate 100. The reflective layer 110 may be formed by stacking a plurality of dielectric layers, and the material of the dielectric layers may include, for example, aluminum oxide (Al₂O₃), silicon dioxide (SiO₂), or niobium pentoxide (Nb₂O₅). In other embodiments, the reflective layer may further cover the sidewalls of the light-emitting element 120 to reflect or deflect laterally emitted light, thereby improving the light emission efficiency of the light-emitting element 120. Similarly, the reflective layer 110 may also be provided in the display panel 10 of FIG. 1 to improve the utilization efficiency of the light energy.

In summary, in a display panel of one embodiment of the disclosure, a light-emitting element is adapted to emit color light with specific wavelength ranges, and a blue phase liquid crystal layer is disposed on the transmission path of the color light. Since the blue phase liquid crystal layer has a narrower reflection bandwidth for specific color light, it can effectively reduce the reflection of ambient light, thereby improving the display contrast of the display panel. In addition, the configuration of the blue phase liquid crystal layer can further increase the light energy utilization efficiency of the color light, thereby enhancing the front-view brightness of the display panel.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. The use of “at least one of...and...” thereof herein may include “one or more of the items contained in the list”. For example, the use of “at least one of A and B” thereof herein may include only A, or only B, or A and B. Similarly, the use of “at least one of A, B, and C” thereof herein may include only A, or only B, or only C, or any combination of A, B, and C. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A display panel, comprising:
a substrate;
a first light-emitting element, disposed on the substrate and adapted to emit a first color light having a first wavelength range;
a second light-emitting element, disposed on the substrate and adapted to emit a second color light having a second wavelength range, wherein the first wavelength range is different from the second wavelength range;
a first blue phase liquid crystal layer, disposed on one side of a first light-emitting surface of the first light-emitting element and overlapping the first light-emitting surface; and
a second blue phase liquid crystal layer, disposed on one side of a second light-emitting surface of the second light-emitting element and overlapping the second light-emitting surface, wherein an average reflectance of the first blue phase liquid crystal layer in the first wavelength range is greater than or equal to 30%, an average reflectance of the first blue phase liquid crystal layer in the second wavelength range is less than 20%, an average reflectance of the second blue phase liquid crystal layer in the second wavelength range is greater than or equal to 30%, and an average reflectance of the second blue phase liquid crystal layer in the first wavelength range is less than 20%.

2. The display panel according to claim 1, further comprising:
a third light-emitting element, disposed on the substrate and adapted to emit a third color light having a third wavelength range; and
a third blue phase liquid crystal layer, disposed on one side of a third light-emitting surface of the third light-emitting element and overlapping the third light-emitting surface, wherein the third wavelength range is different from the first wavelength range and the second wavelength range, an average reflectance of the third blue phase liquid crystal layer in the third wavelength range is greater than or equal to 30%, an average reflectance of the third blue phase liquid crystal layer in the first wavelength range and the second wavelength range is less than 20%, and an average reflectance of each of the first blue phase liquid crystal layer and the second blue phase liquid crystal layer in the third wavelength range is less than 20%.

3. The display panel according to claim 1, wherein the first blue phase liquid crystal layer is further disposed on one side of the second light-emitting surface of the second light-emitting element and overlaps the second light-emitting surface, and the second blue phase liquid crystal layer is further disposed on one side of the first light-emitting surface of the first light-emitting element and overlaps the first light-emitting surface.

4. The display panel according to claim 1, wherein an orthographic projection of the first blue phase liquid crystal layer on the substrate does not overlap an orthographic projection of the second blue phase liquid crystal layer on the substrate.

5. The display panel according to claim 4, further comprising:
an light-absorbing layer, disposed between the first blue phase liquid crystal layer and the second blue phase liquid crystal layer, and not overlapping the first light-emitting surface and the second light-emitting surface.

6. The display panel according to claim 1, wherein the first color light and the second color light each include a first portion and a second portion, each of the first blue phase liquid crystal layer and the second blue phase liquid crystal layer is adapted to reflect the first portion and allow the second portion to pass through, the first portion has a first circular polarization state, the second portion has a second circular polarization state, and the first circular polarization state is different from the second circular polarization state.

7. The display panel according to claim 1, further comprising:
a light-absorbing layer, disposed on the substrate and located between the first light-emitting element and the second light-emitting element, wherein the light-absorbing layer has a surface facing away from the substrate, and the surface of the light-absorbing layer is aligned with the first light-emitting surface and the second light-emitting surface.

8. The display panel according to claim 1, further comprising:
an adhesive layer, connecting the first light-emitting surface to the first blue phase liquid crystal layer, and connecting the second light-emitting surface to the second blue phase liquid crystal layer.

9. The display panel according to claim 1, wherein a reflective layer is provided between the substrate and each of the first light-emitting element and the second light-emitting element.

10. The display panel according to claim 1, further comprising:
a circular polarizer, disposed overlapping the first light-emitting surface and the second light-emitting surface, wherein the first blue phase liquid crystal layer and the second blue phase liquid crystal layer are located between the substrate and the circular polarizer.
